(19) United States
(12) Patent Application Publication
(10) Pub. No.: US 2026/0196450 A1
(43) Pub. Date: Jul. 9, 2026

(54) WAFER PLACEMENT TABLE

(71) Applicant: NGK INSULATORS, LTD., Nagoya-shi (JP)

(72) Inventors: Taro USAMI, Ginan-town (JP); Tatsuya KUNO, Nagoya-shi (JP)

(21) Appl. No.: 19/553,534

(22) Filed: Mar. 2, 2026

Related U.S. Application Data
(63) Continuation of application No. PCT/JP2025/028487, filed on Aug. 12, 2025.

(30) Foreign Application Priority Data
Sep. 12, 2024 (JP) 2024-158405

(51) Int. Cl. H01J 37/32

(52) U.S. Cl. CPC H01J 37/32715; H01J 37/3244; H01J 2237/2007

(57) ABSTRACT

A wafer placement table includes: a ceramic plate having a wafer placement surface on its upper surface and incorporating an electrode; an electrically conductive plate disposed on a lower-surface side of the ceramic plate; a joint layer joining the ceramic plate and the electrically conductive plate; a ceramic plate penetrating portion extending through the ceramic plate; an insulating gas passage plug provided in the ceramic plate penetrating portion and allowing gas to pass through its interior; a gas introduction passage provided at least inside the joint layer and the electrically conductive plate, and communicating with the ceramic plate penetrating portion; and wherein the joint layer has a structure in which an insulator layer and an electrically conductive layer are laminated, and the electrically conductive layer is exposed in a joint layer penetrating portion which is a portion of the gas introduction passage that penetrates the joint layer.

### CROSS-REFERENCE TO RELATED APPLICATION

This application is a continuation application of PCT/JP2025/028487, filed on Aug. 12, 2025, which claims priority benefit of Japanese Patent Application No. 2024-158405 filed on Sep. 12, 2024, the entire contents of which are incorporated herein by reference.

### BACKGROUND OF THE INVENTION

### 1. Field of the Invention

The present invention relates a wafer placement table.

### 2. Description of the Related Art

Hitherto, there is known a wafer placement table that includes a ceramic plate having a wafer placement surface on its upper surface and a base plate joined to a lower surface of the ceramic plate via a joint layer and having a gas introduction passage. In PTL 1, in the thus configured wafer placement table, an electrically insulating first porous portion disposed in a through-hole of the ceramic plate, and an electrically insulating second porous portion fitted to a recess provided on a ceramic plate side of the base plate so as to be opposed to the first porous portion are provided. Gas supplied to the gas introduction passage passes through the second porous portion and the first porous portion and flows into the space between the wafer placement surface and a wafer. The gas is used to cool an object. As the joint layer that joins the ceramic plate and the base plate, for example, a cured silicone adhesive is used. In the description, with the first porous portion and the second porous portion, while the flow rate of gas from the gas introduction passage to the wafer placement surface is ensured, it is possible to suppress occurrence of discharge (arc discharge) due to plasma at the time when a wafer is processed.

### CITATION LIST

### Patent Literature

PTL 1: JP 2020-72262 A

### SUMMARY OF THE INVENTION

However, even with the electrically insulating second porous portion as described in PTL 1, there has been a case where discharge occurs around a base plate-side end of the first porous portion. Further, it is conceivable to change the joint layer from an insulator such as a resin to an electrically conductor such as a metal in order to suppress this discharge, but in general, an electrically conductor has a lower thermal resistance (higher thermal conductivity) than an insulator, so when the joint layer is an electrically conductor, there is a problem that the wafer tends to be cooled.

The present invention is made to solve such inconvenience, and it is a main object to suppress cooling of the wafer, while suppressing discharge around an electrically conductive plate-side end of an insulating gas passage plug.

The present invention employs the following manner to achieve the above-described main object.
[1] A wafer placement table of the present invention includes: a ceramic plate having a wafer placement surface on its upper surface and incorporating an electrode; an electrically conductive plate disposed on a lower-surface side of the ceramic plate; a joint layer joining the ceramic plate and the electrically conductive plate; a ceramic plate penetrating portion extending through the ceramic plate; an insulating gas passage plug provided in the ceramic plate penetrating portion and allowing gas to pass through its interior; a gas introduction passage provided at least inside the joint layer and the electrically conductive plate, and communicating with the ceramic plate penetrating portion; and wherein the joint layer has a structure in which an insulator layer and an electrically conductive layer are laminated, and the electrically conductive layer is exposed in a joint layer penetrating portion which is a portion of the gas introduction passage that penetrates the joint layer.

In this wafer placement table, the joint layer that joins the ceramic plate and the electrically conductive plate has the structure in which the insulator layer and the electrically conductive layer are laminated. Accordingly, as compared with a case in which the joint layer is constituted entirely of an electrically conductor, the thermal resistance of the joint layer can be more easily increased, so that cooling of the wafer can be suppressed. Further, because the electrically conductive layer is exposed in the joint layer penetrating portion which is the portion of the gas introduction passage that penetrates the joint layer, discharge around an electrically conductive plate-side end of the insulating gas passage plug can be suppressed. From the foregoing, in this wafer placement table, it is possible to suppress cooling of the wafer, while suppressing discharge around the electrically conductive plate-side end of the insulating gas passage plug.
[2] The above-described wafer placement table (the wafer placement table according to [1]) may further comprise a conduction member that electrically connects the electrically conductive plate and the electrically conductive layer. By this, an electrical potential can be supplied to the electrically conductive layer by electrically connecting the electrically conductive plate and the electrically conductive layer, so that the two can be brought to substantially the same electrical potential. Accordingly, the effect of suppressing discharge around the electrically conductive plate-side end of the insulating gas passage plug is enhanced.
[3] In the above-described wafer placement table (the wafer placement table according to [2]), the conduction member may be disposed at a position different from the joint layer penetrating portion.
[4] In the above-described wafer placement table (the wafer placement table according to any one of [1] to [3]), a distance L1 between the lower surface of the ceramic plate and the electrically conductive layer in an up-down direction may be 200 μm or less. By making the distance L1 200 μm or less, the height of a space between the lower surface of the insulating gas passage plug and the electrically conductive layer becomes small, and therefore the effect of suppressing discharge around the electrically conductive plate-side end of the insulating gas passage plug is enhanced.
[5] In the above-described wafer placement table (the wafer placement table according to [4]), the distance L1 may be 100 μm or less. In this case, since the height of the space between the lower surface of the insulating gas passage plug and the electrically conductive layer becomes further smaller, the above-described effect of suppressing discharge is further enhanced.
[6] The above-described wafer placement table (the wafer placement table according to any one of [1] to [5]), may further comprise an electrically conductive gas passage member that is provided in the gas introduction passage, contacts a lower surface of the insulating gas passage plug, is electrically connected to the electrically conductive plate and/or the electrically conductive layer, and allows gas to pass between the insulating gas passage plug and the gas introduction passage. In this case, as compared with, for example, a case where an insulating porous member is present on the lower-surface side of the insulating gas passage plug, an electrically potential difference is less likely to occur around the electrically conductive plate-side end of the insulating gas passage plug. Accordingly, discharge around the electrically conductive plate-side end of the insulating gas passage plug can be more effectively suppressed.
[7] In the above-described wafer placement table (the wafer placement table according to [6]), the electrically conductive gas passage member may include an electrically conductive elastic body that presses the insulating gas passage plug upward with an elastic force. In this case, electrical conduction from a contact portion with the insulating gas passage plug of the electrically conductive gas passage member to the electrically conductive plate and/or the electrically conductive layer is likely to be maintained.
[8] In the above-described wafer placement table (the wafer placement table according to [7]), the electrically conductive elastic body may be a plate spring.
[9] In the above-described wafer placement table (the wafer placement table according to any one of [6] to [8]), the electrically conductive gas passage member may include a covering layer that covers the lower surface of the insulating gas passage plug. In this case, the covering layer may be a dense layer having a hole that allow passage of gas. The covering layer may instead be a porous layer that allows passage of gas. Alternatively, the covering layer may cover a part of the lower surface of the insulating gas passage plug and allow passage of gas through an uncovered portion of the lower surface.

### BRIEF DESCRIPTION OF THE DRAWINGS

FIG. 1 is a plan view of a wafer placement table 10.

FIG. 2 is a sectional view taken along the line A-A in FIG. 1.

FIG. 3 is an explanatory view showing positions of an upper surface 72a of a leaf spring 72, an internal gas passage 55a, and a joint layer penetrating portion 64 in plan view.

FIG. 4 is a perspective view of the plate spring 72 of an electrically conductive gas passage member 70.

FIG. 5 is a sectional view of the wafer placement table 10, taken along a horizontal plane passing through the gas second passage 62 when viewed from above.

FIG. 6 is a sectional view of the wafer placement table 10, taken along a horizontal plane passing through a refrigerant flow path 32 when viewed from above.

FIG. 7 is a view in which the refrigerant flow path 32 and the like are drawn in the plan view of the wafer placement table 10.

FIGS. 8A to 8F are manufacturing process charts of the wafer placement table 10.

FIGS. 9A and 9B are explanatory views showing a state in which the plate spring 72 is pressed by a dense plug 55 during manufacture of the wafer placement table 10.

FIG. 10 is a partially enlarged sectional view showing a conduction member 49.

FIG. 11 is a partially enlarged sectional view showing a joint layer 140.

FIG. 12 is a partially enlarged sectional view showing a porous plug 155 and a covering layer 171.

FIG. 13 is a partially enlarged sectional view showing an electrically conductive gas passage member 270.

FIG. 14 is a partially enlarged sectional view showing a plate spring 472.

FIG. 15 is a perspective view of the plate spring 472.

FIG. 16 is a partially enlarged sectional view showing an electrically conductive elastic body 572.

FIG. 17 is a partially enlarged sectional view showing a first electrically conductive layer 645 of a modified example.

### DETAILED DESCRIPTION OF THE INVENTION

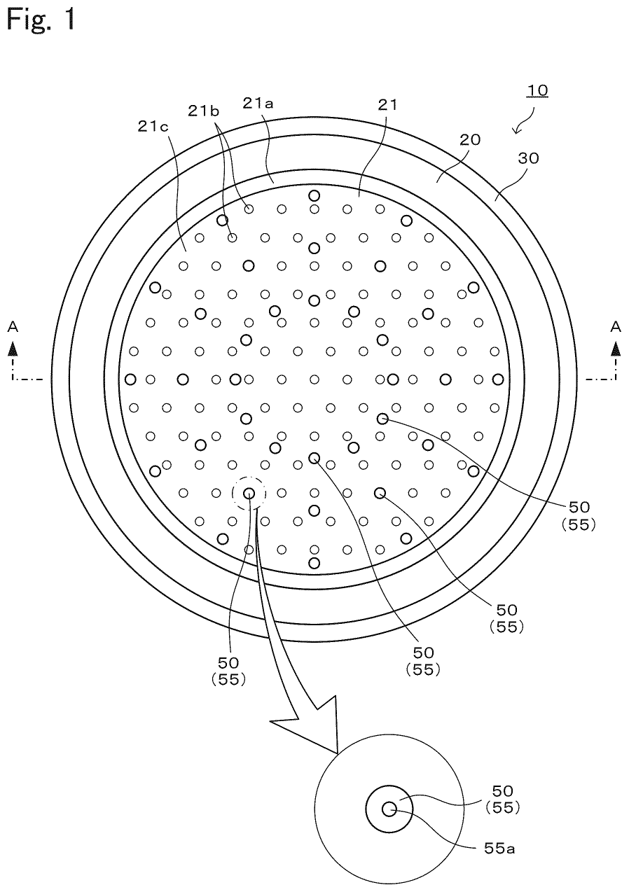

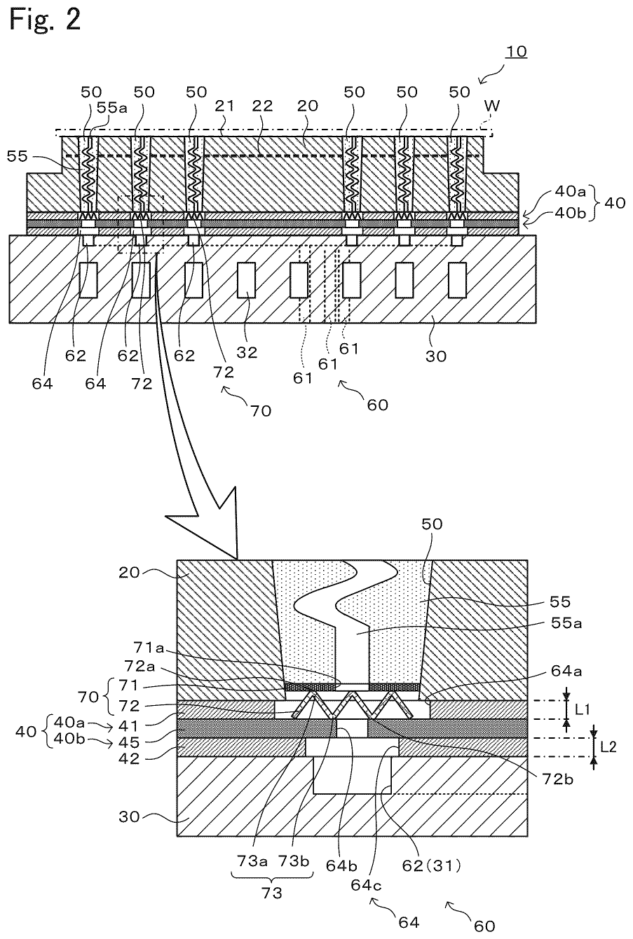

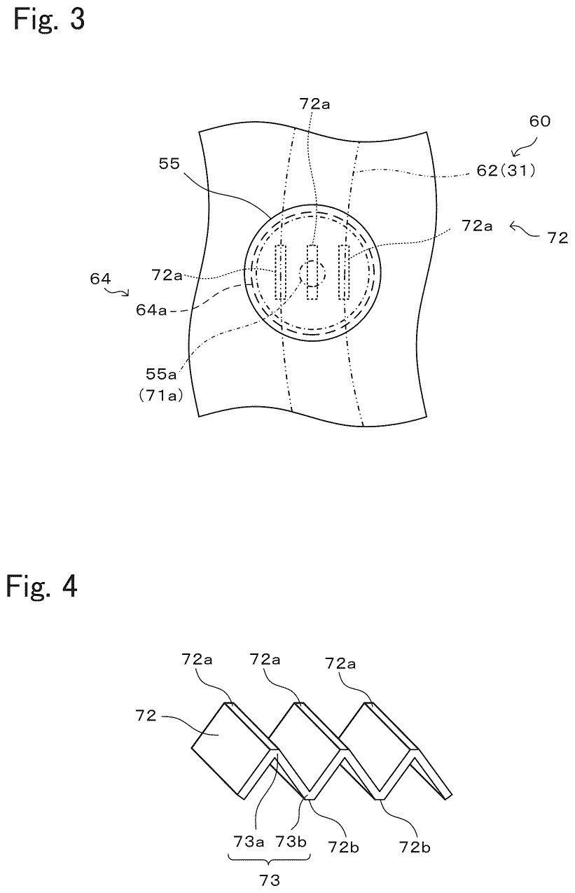

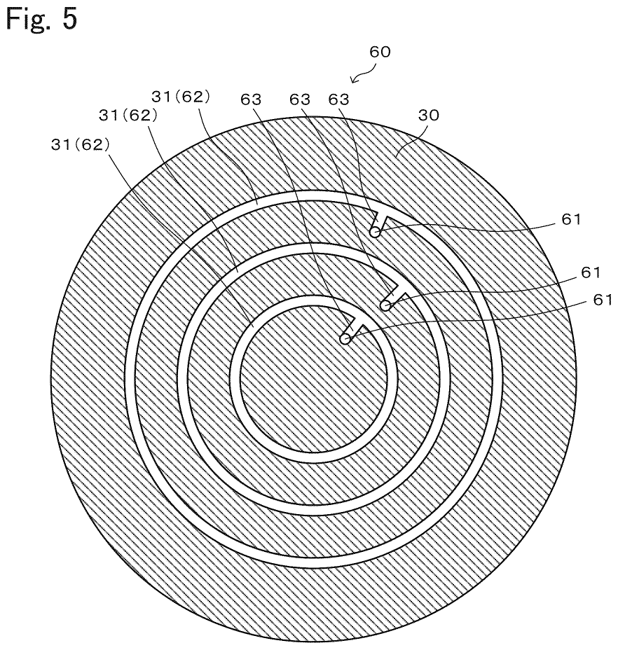

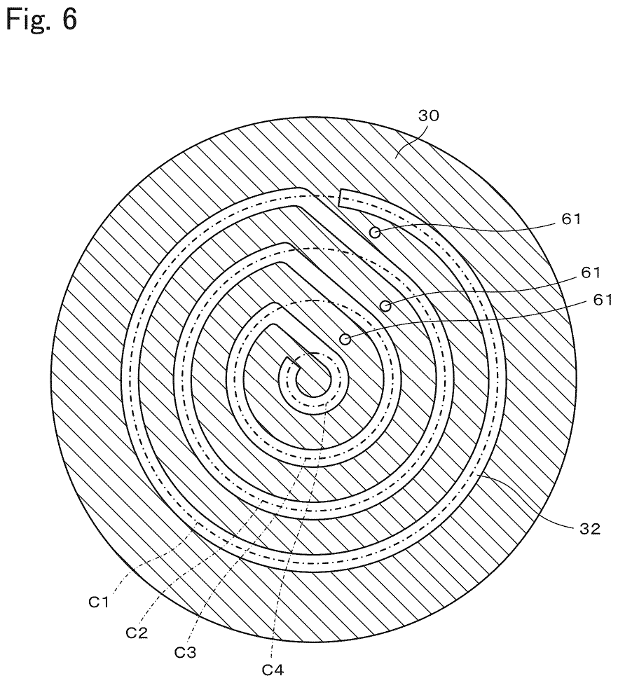

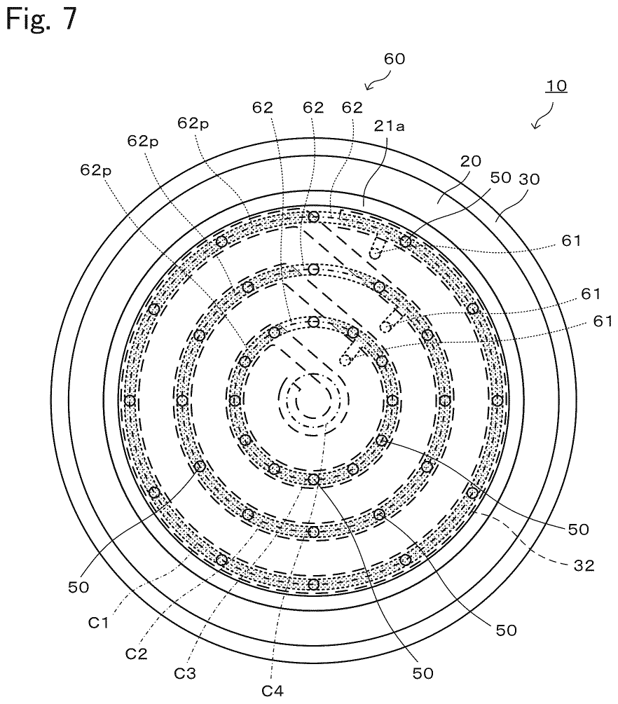

Next, an embodiment of the present invention will be described with reference to the accompanying drawings. FIG. 1 is a plan view of a wafer placement table 10, FIG. 2 is a sectional view taken along line A-A in FIG. 1, FIG. 3 is an explanatory view showing positions of an upper surface 72a of a leaf spring 72, an internal gas passage 55a, and a joint layer penetrating portion 64 in plan view, FIG. 5 is a sectional view of the wafer placement table 10, taken along a horizontal plane passing through the gas second passage 62 when viewed from above, FIG. 6 is a sectional view of the wafer placement table 10, taken along a horizontal plane passing through a refrigerant flow path 32 when viewed from above, and FIG. 7 is a view in which the refrigerant flow path 32 and the like are drawn in the plan view of the wafer placement table 10. In the specification, the words “up” and “down” do not indicate an absolute positional relationship. Therefore, depending on the orientation of the wafer placement table 10, “up” and “down” can be “down” and “up” or can be “left” and “right” or can be “front” and “rear”.

As shown in FIG. 2, the wafer placement table 10 includes a ceramic plate 20, a electrically conductive plate 30, a joint layer 40, a ceramic plate penetrating portion 50, a gas introduction passage 60, and an electrically conductive gas passage member 70.

The ceramic plate 20 is a ceramic disk (e.g., diameter 300 mm, thickness 5 mm) such as an alumina sintered body or an aluminum nitride sintered body. An upper surface of the ceramic plate 20 serves as a wafer placement surface 21 on which a wafer W is placed. The ceramic plate 20 incorporates an electrode 22. As shown in FIG. 1, an annular seal band 21a is formed along an outer edge of the wafer placement surface 21, and a plurality of circular small projections 21b are formed over the entire area inside the seal band 21a. The seal band 21a and the circular small projections 21b have the same height, which is, for example, several μm to several tens of μm. The electrode 22 is a planar mesh electrode used as an electrostatic electrode and is connected to an external DC power supply via a power supply member (not shown). A low-pass filter may be disposed in the middle of the power supply member. The power supply member is electrically insulated from the insulator layer 40a of the joint layer 40 and from the electrically conductive plate 30. When a DC voltage is applied to the electrode 22, the wafer W is attracted and fixed to the wafer placement surface 21 (specifically, to an upper surface of the seal band and upper surfaces of the circular small projections) by electrostatic attraction, and when application of the DC voltage is stopped, the attraction and fixation of the wafer W to the wafer placement surface 21 is released. A portion of the wafer placement surface 21 where neither the seal band 21a nor the circular small projections 21b are provided is referred to as a reference surface 21c.

The electrically conductive plate 30 is a disk having good thermal conductivity (a disk having a diameter equal to or greater than the diameter of the ceramic plate 20). The refrigerant flow path 32 in which refrigerant circulates is formed in the electrically conductive plate 30. Refrigerant flowing through the refrigerant flow path 32 is preferably liquid and preferably has electrically insulating properties. Examples of the liquid having electrically insulating properties include fluorinated inert liquid. The refrigerant flow path 32 is formed in a one-stroke pattern from one end (inlet) to the other end (outlet) over the entire area of the electrically conductive plate 30 in plan view. As shown in FIG. 6, the refrigerant flow path 32 is provided so as to be routed in a one-stroke pattern from one end to the other end in accordance with multiple circles disposed such that a plurality of imaginary circles (dash-dotted line circles C1 to C4; here, the circles C1 to C4 are concentric circles) having different diameters in plan view. Specifically, to route the refrigerant flow path 32 in a one-stroke pattern from one end to the other end, the refrigerant flow path 32 is routed so as to trace the imaginary circles while connecting two inner and outer imaginary circles of the multiple circles. A supply port and collection port of an external refrigerant apparatus (not shown) are respectively connected to one end and the other end of the refrigerant flow path 32. Refrigerant supplied from the supply port of the external refrigerant apparatus to one end of the refrigerant flow path 32 passes through the refrigerant flow path 32 and then returns to the collection port of the external refrigerant apparatus from the other end of the refrigerant flow path 32, the refrigerant is adjusted in temperature, and then the refrigerant is supplied to one end of the refrigerant flow path 32 through the supply port again. The electrically conductive plate 30 is connected to a radio-frequency (RF) power supply and is also used as an RF electrode.

Examples of the material of the electrically conductive plate 30 include a metal material and a composite material of metal and ceramics. Examples of the metal material include Al, Ti, Mo, and alloys of them. Examples of the composite material of metal and ceramics include a metal matrix composite material (MMC) and a ceramic matrix composite material (CMC). Specific examples of such composite materials include a material including Si, SiC, and Ti (also referred to as SiSiCTi), a material obtained by impregnating an SiC porous body with Al and/or Si, and a composite material of Al₂O₃ and TiC. A material having a coefficient of thermal expansion close to that of the material of the ceramic plate 20 is preferably selected as the material of the electrically conductive plate 30.

The joint layer 40 joins a lower surface of the ceramic plate 20 and an upper surface of the electrically conductive plate 30. The joint layer 40 has a structure in which an insulator layer 40a and an electrically conductive layer 40b are laminated. In this embodiment, the insulator layer 40a has two layers, a first insulator layer 41 and a second insulator layer 42, and the electrically conductive layer 40b has one layer, a first electrically conductive layer 45. The first insulator layer 41, the first electrically conductive layer 45, and the second insulator layer 42 are laminated in this order from top to bottom, and the insulator layer 40a and the electrically conductive layer 40b are alternately laminated. As the material of the insulator layer 40a (here, the first insulator layer 41 and the second insulator layer 42), a resin having insulating properties, such as silicone resin, acrylic resin, polyimide resin, and epoxy resin, is exemplified. As the material of the electrically conductive layer 40b (here, the first electrically conductive layer 45), for example, a metal is exemplified. It is preferable that the material of the electrically conductive layer 40b be low resistance and nonmagnetic. Examples of the nonmagnetic metal used for the electrically conductive layer 40b include Al and Cu, with Al being particularly preferable. The second insulator layer 42 is present between the first electrically conductive layer 45 and the electrically conductive plate 30, and the first electrically conductive layer 45 and the electrically conductive plate 30 are not directly electrically connected.

A distance L1 (see FIG. 2) between the lower surface of the ceramic plate 20 and the electrically conductive layer 40b (here, the first electrically conductive layer 45) in the up-down direction is preferably 200 μm or less and more preferably 100 μm or less. Likewise, a distance L2 between the upper surface of the electrically conductive plate 30 and the electrically conductive layer 40b (here, the first electrically conductive layer 45) in the up-down direction is preferably 200 μm or less and more preferably 100 μm or less. In this embodiment, the distance L1 is equal to the thickness of the first insulator layer 41. The distance L2 is equal to the thickness of the second insulator layer 42.

As shown in FIG. 2, the ceramic plate penetrating portion 50 is a hole that penetrates the ceramic plate 20 in the up-down direction. The ceramic plate penetrating portion 50 is a gas passage from the lower surface of the ceramic plate 20 to the reference surface 21c (FIG. 1) of the wafer placement surface 21. As shown in FIG. 1, a plurality (36 here) of ceramic plate penetrating portions 50 are provided. As shown in FIG. 2, the ceramic plate penetrating portion 50 is a space having a shape (e.g., an inverted frustoconical shape) whose cross-sectional area decreases from an upper opening toward a lower opening. The ceramic plate penetrating portion 50 has an insulating dense plug 55 (an example of the insulating gas passage plug) that allows gas to flow in the up-down direction.

The dense plug 55 is a member having, like the shape of the ceramic plate penetrating portion 50, a shape whose cross-sectional area decreases from an upper surface toward a lower surface (e.g., a frustoconical shape). The dense plug 55 has a gas internal passage 55a. In FIG. 3, a contour of the upper surface of the dense plug 55 is shown by a solid line, and a contour of the lower surface of the dense plug 55 and a contour of a lower-end opening of the gas internal passage 55a are each shown by a dash-dotted line. The gas internal passage 55a is a passage that allows gas to flow between an upper-surface side and a lower-surface side of the dense plug 55. The gas internal passage 55a is a passage penetrating the upper surface side and the lower surface side of the dense plug 55 while bending, and more specifically is configured as a zigzag passage. As another example of a passage penetrating while bending, a spiral passage is exemplified. The gas internal passage 55a may alternatively be a straight through-hole along the up-down direction. A diameter of a flow cross section of the gas internal passage 55a is preferably 0.1 mm to 1 mm. One dense plug 55 may have a plurality of gas internal passages 55a. A porosity of a dense portion of the dense plug 55 is preferably less than 0.1%. The dense plug 55 is fixed by being press-fitted into the ceramic plate penetrating portion 50. As the dense plug 55, a ceramic such as alumina or aluminum nitride can be used. The dense plug 55 may be manufactured by, for example, firing a molded body molded by using a 3D printer or firing a molded body molded by mold cast. The details of the dense plug having a gas internal passage that extends through while being bent, and mold cast are described in, for example, Japanese Patent No. 7149914 or the like.

An upper surface of the dense plug 55 is at the same height as the reference surface 21c of the wafer placement surface 21. A lower surface of the dense plug 55 is covered with a covering layer 71 that is a part of the electrically conductive gas passage member 70. As shown in FIG. 2, the lower surface of the dense plug 55 is located above a lower opening surface of the ceramic plate penetrating portion 50 (the same height as the lower surface of the ceramic plate 20). The lower surface of the dense plug 55 may be at the same height as the lower opening surface of the ceramic plate penetrating portion 50. The lower surface of the dense plug 55 may be located below the lower opening surface of the ceramic plate penetrating portion 50. That is, a lower end of the dense plug 55 may project below the lower surface of the ceramic plate 20.

The gas introduction passage 60 is provided at least inside the joint layer 40 and the electrically conductive plate 30 and is a passage of gas, which communicates with the ceramic plate penetrating portion 50. The gas introduction passage 60 includes a gas first passages 61, gas second passages 62, gas auxiliary passages 63 (FIG. 5), and bonding layer penetrating portions 64. The gas introduction passage 60 includes gas passages (the gas first passages 61, the gas second passages 62, and the gas auxiliary passages 63) provided in the electrically conductive plate 30, and gas passages (bonding layer penetrating portions 64) provided in the bonding layer 40.

The gas first passages 61 extend through the electrically conductive plate 30 in the up and down direction. The gas first passages 61 extend through the electrically conductive plate 30 in the up and down direction between parts of the refrigerant flow path 32. The plurality of (hereinafter, three) gas first passages 61 is provided.

The gas second passages 62 are provided parallel to the wafer placement surface 21 at the interface between the bonding layer 40 and the electrically conductive plate 30. The state “parallel” includes not only a completely parallel state but also a state that falls within the range of an allowable error (for example, tolerance) even when the state is not completely parallel. The gas second passages 62 each have a recessed groove 31 (first recessed portion) provided on the upper surface of the electrically conductive plate 30 and each are formed when the upper surface of the recessed groove 31 is covered with the bonding layer 40. As shown in FIG. 7, each of the gas second passages 62 is provided in an annular shape so as to overlap any one of the plurality of imaginary circles C1 to C4 in a plan view. Specifically, of the three gas second passages 62, the first gas second passage 62 from the outer periphery of the wafer placement table 10 overlaps the imaginary circle C1 with the greatest diameter, the second gas second passage 62 overlaps the imaginary circle C2 with the second greatest diameter, and the third gas second passage 62 overlaps the imaginary circle C3 with the third greatest diameter. Each of the gas second passages 62 has an overlapping part 62p (the shaded parts in FIG. 7) that overlaps the refrigerant flow path 32 along the refrigerant flow path 32 in a plan view.

Each of the gas auxiliary passages 63 is a passage that connects the gas first passage 61 with the gas second passage 62 and is provided parallel to the wafer placement surface 21 at the interface between the bonding layer 40 and the electrically conductive plate 30. The plurality of (here, 12) ceramic plate penetrating portions 50 is provided for each gas second passage 62; however, the number of the gas first passages 61 and the number of the gas auxiliary passages 63 are less than the number of the ceramic plate penetrating portions 50 (here, one for each gas second passage 62).

As shown in FIG. 2, the joint layer penetrating portion 64 is a portion of the gas introduction passage 60 that penetrates the joint layer 40 in the up-down direction. The joint layer penetrating portion 64 is a gas passage from the upper surface of the electrically conductive plate 30 to the lower surface of the ceramic plate 20. A plurality (36 here) of joint layer penetrating portions 64 are provided and are arranged in one-to-one correspondence with the ceramic plate penetrating portions 50. Each of the plurality of joint layer penetrating portions 64 includes a through-hole 64a provided in the first insulator layer 41, a through-hole 64b provided in the first electrically conductive layer 45, and a through-hole 64c provided in the second insulator layer 42. The joint layer penetrating portion 64 is configured by these through-holes 64a to 64c being communicated in the up-down direction. Accordingly, portions of the first insulator layer 41, the second insulator layer 42, and the first electrically conductive layer 45 that constitute inner peripheral surfaces of the through-holes 64a to 64c are exposed to the joint layer penetrating portion 64. The through-hole 64a is a circular hole in plan view (see FIG. 3). The through-holes 64b and 64c are also circular holes in plan view. In this embodiment, as shown in FIG. 2, a diameter of the through-hole 64a is larger than a diameter of the lower surface of the dense plug 55 and a diameter of the lower opening surface of the ceramic plate penetrating portion 50. A diameter of the through-hole 64b is smaller than the diameter of the through-hole 64a. Accordingly, a portion of the upper surface of the first electrically conductive layer 45 is exposed in the through-hole 64a of the first insulator layer 41, and therefore this portion is exposed to the joint layer penetrating portion 64. A diameter of the through-hole 64b is smaller than a diameter of the through-hole 64c. Accordingly, a portion of the lower surface of the first electrically conductive layer 45 is exposed in the through-hole 64c of the second insulator layer 42, and therefore this portion is exposed to the joint layer penetrating portion 64. A diameter of the through-hole 64c is larger than a width of the recessed groove 31.

The electrically conductive gas passage member 70 is provided in the gas introduction passage 60 so as to contact the lower surface of the dense plug 55, be electrically connected to the electrically conductive plate 30 and/or the electrically conductive layer 40b, and allow gas to pass between the dense plug 55 and the gas introduction passage 60. The electrically conductive gas passage member 70 includes a covering layer 71 and a plate spring 72 (an example of an electrically conductive elastic body). The covering layer 71 covers the lower surface of the dense plug 55 and thus is in contact with the lower surface of the dense plug 55. The covering layer 71 is formed as a dense layer and has hole 71a that allow gas to pass in the up-down direction. The hole 71a communicate an opening of the gas internal passage 55a on the lower surface of the dense plug 55 with the gas introduction passage 60. The covering layer 71 can be manufactured, for example, by forming, before the dense plug 55 is press-fitted into the ceramic plate 20, the covering layer on the lower surface of the dense plug 55 by sputtering or electroless plating and making the hole 71a. Examples of the material of the covering layer 71 include metal materials, and metals having excellent corrosion resistance such as Au, Ag, Al, Ti, SUS316L, or Hastelloy (Ni—Fe—Mo alloy; Hastelloy is a registered trademark) are preferable.

The plate spring 72 is an elastic body that presses the dense plug 55 upward with an elastic force. As the material of the plate spring 72, a conductor can be used, and more specifically a metal material such as Al, Ti, Mo or alloys thereof, steel, SUS316L, and Hastelloy (registered trademark) can be used. The plate spring 72 is manufactured, for example, by bending a metal plate, and in this embodiment has a shape in which a metal plate is bent in a zigzag. A zigzag return direction of the plate spring 72 is along the up-down direction. That is, the plate spring 72 has a plurality of return portions 73 returned along the up-down direction. The return portions 73 of the plate spring 72 are formed in a V-shape. As the plurality of return portions 73, the plate spring 72 has one or more (a plurality, specifically three here) first return portions 73a returned from above to below and one or more (a plurality, specifically two here) second return portions 73b returned from below to above. Accordingly, in this embodiment, a number of times of return of the plate spring 72 is a plurality of times (five times here). However, the number of times of return only needs to be one or more. An upper surface 72a of the plate spring 72 (an upper surface of the first return portion 73a of the plate spring 72; see also FIG. 4) is in contact with a lower surface of the covering layer 71. Thus, the plate spring 72 and the covering layer 71 are electrically connected. The plate spring 72 is disposed inside the joint layer penetrating portion 64 among the gas introduction passage 60. In this embodiment, since the lower surface of the dense plug 55 and the lower surface of the covering layer 71 are located above the lower opening surface of the ceramic plate penetrating portion 50, the plate spring 72 is also disposed inside the ceramic plate penetrating portion 50. That is, the plate spring 72 is disposed to straddle the inside of the ceramic plate penetrating portion 50 and the inside of the joint layer penetrating portion 64. The through-hole 64a is formed larger than the plate spring 72, and the through-hole 64b is formed smaller than the plate spring 72. Thus, the plate spring 72 is disposed in the through-hole 64a, and a lower surface 72b of the plate spring 72 (a lower surface of the second return portion 73b of the plate spring 72; see also FIG. 4) contacts a portion of the upper surface of the first electrically conductive layer 45 that is exposed in the through-hole 64a of the first insulator layer 41, whereby the plate spring 72 is supported by the first electrically conductive layer 45. Thus, the plate spring 72 is electrically connected to the first electrically conductive layer 45. Accordingly, the covering layer 71, the plate spring 72, and the first electrically conductive layer 45 are electrically connected. Further, as described above, since the first electrically conductive layer 45 and the electrically conductive plate 30 are not directly electrically connected, the plate spring 72 and the electrically conductive plate 30 are not directly electrically connected.

In this embodiment, since the zigzag return direction of the plate spring 72 is along the up-down direction, a principal expansion/contraction direction of the plate spring 72 is not the up-down direction in FIG. 2, that is, not the direction pressing the dense plug 55, but the left-right direction in FIG. 2. That is, the plate spring 72 is disposed sideways. However, since the plate spring 72 is zigzagged and becomes a state in which it is extended in a crosswise direction perpendicular to the up-down direction when the plate spring 72 is pressed from above by the dense plug 55 (a state in which the plate of the plate spring 72 becomes more inclined than in the up-down direction), an elastic force is also exerted in the up-down direction from the plate spring 72 as a force tending to return the extension (a force by which the plate of the plate spring 72 tends to return from an inclined state to a direction along the up-down direction). By this elastic force, the plate spring 72 presses the dense plug 55 upward. Similarly, the plate spring 72 presses the first electrically conductive layer 45 and the electrically conductive plate 30 downward with an elastic force.

At least one of a shape or an arrangement position of the plate spring 72 is adjusted so that the plate spring 72 does not completely close the hole 71a of the covering layer 71 (and the lower-end opening of the gas internal passage 55a) and block gas flow. In this embodiment, as shown in FIGS. 2 and 3, the width of each of three upper surfaces 72a among the contact surfaces with the covering layer 71 of the plate spring 72 is smaller than the opening diameter of the hole 71a, whereby the plate spring 72 is adjusted so as not to completely close the hole 71a (and the lower-end opening of the gas internal passage 55a) regardless of the arrangement position. As described above, since the covering layer 71 has the hole 71a and the plate spring 72 does not block gas flow through the hole 71a, gas in the gas introduction passage 60 can flow into the ceramic plate penetrating portion 50 through the inside and/or around the electrically conductive gas passage member 70. In this embodiment, as shown in FIGS. 2 and 3, one of the three upper surfaces 72a of the plate spring 72 does not completely close the hole 71a of the covering layer 71 but closes part of the hole 71a. That is, in plan view, the upper surface 72a of the plate spring 72 partially overlaps the hole 71a. However, it is preferable that, in plan view, the upper surface 72a of the plate spring 72 does not overlap the hole 71a at all.

In this embodiment, a plurality (36 here) of electrically conductive gas passage members 70 are provided and are arranged in one-to-one correspondence with the dense plugs 55. That is, the covering layers 71 and the plate springs 72 are each arranged in one-to-one correspondence with the dense plugs 55.

Next, an example of use of the thus configured wafer placement table 10 will be described. Initially, in a state where the wafer placement table 10 is placed in a chamber (not shown), a wafer W is mounted on the wafer placement surface 21. Then, the inside of the chamber is decompressed by a vacuum pump and adjusted into a predetermined degree of vacuum, electrostatic attraction force is generated by applying a direct-current voltage to the electrode 22 of the ceramic plate 20, and the wafer W is attracted and fixed to the wafer placement surface 21 (specifically, the upper surface of the seal band 21a or the upper surfaces of the circular small projections 21b). Subsequently, the inside of the chamber is set to a reaction gas atmosphere with a predetermined pressure (for example, several tens to several hundreds of pascals). In this state, plasma is generated by applying an RF voltage between an upper electrode (not shown) provided at a ceiling part in the chamber and the electrically conductive plate 30 of the wafer placement table 10. The surface of the wafer W is processed by the generated plasma. Refrigerant circulates through the refrigerant flow path 32 of the electrically conductive plate 30. Back-side gas is introduced from a gas cylinder (not shown) to the gas first passages 61 of the gas introduction passage 60. Heat transfer gas (for example, He gas or the like) may be used as the back-side gas. Back-side gas introduced into the gas first passages 61 is distributed to the plurality of ceramic plate penetrating portions 50 through the gas auxiliary passages 63, the gas second passages 62, and the joint layer penetrating portion 64 in this order and supplied into the space between the back side of the wafer W and the reference surface 21c of the wafer placement surface 21 to be encapsulated. With the presence of the back-side gas, heat transfer between the wafer W and the ceramic plate 20 is efficiently performed. Since the dense plug 55 is provided in the ceramic plate penetrating portion 50, it is possible to reduce discharge in the ceramic plate penetrating portion 50. Furthermore, because the gas internal passage 55a is a bent passage, discharge in the gas internal passage 55a can be suppressed as compared with a straight passage.

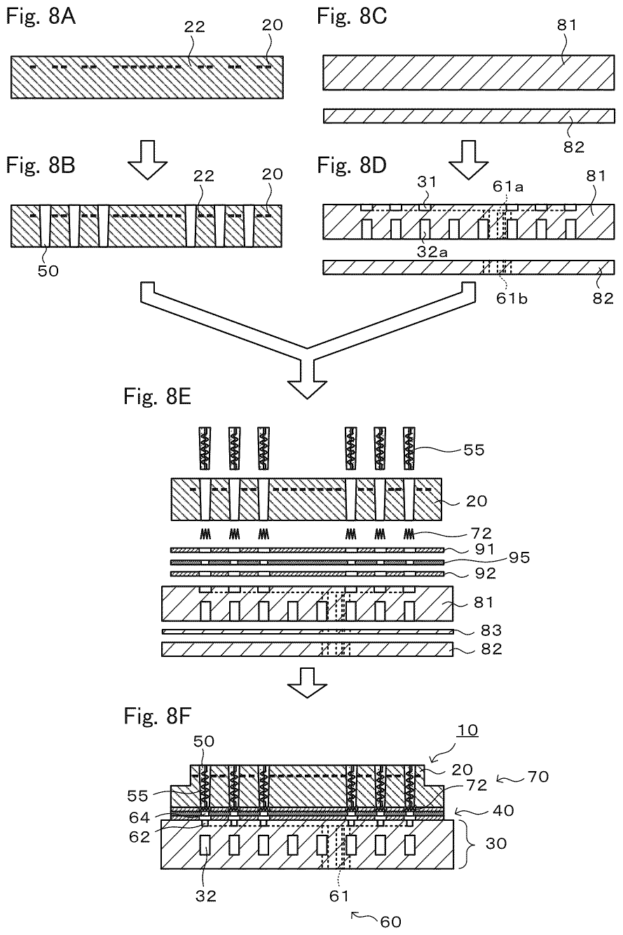

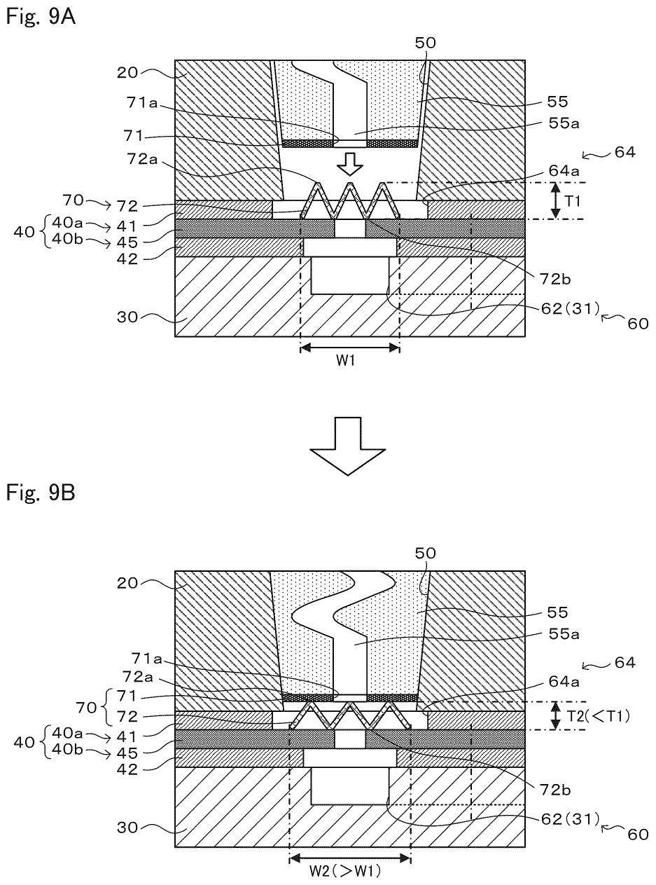

Next, an example of manufacture of the wafer placement table 10 will be described with reference to FIGS. 8A to 8F and 9A and 9B. FIGS. 8A to 8F are manufacturing process charts of the wafer placement table 10. FIGS. 9A and 9B are explanatory views showing a state in which the plate spring 72 is pressed by a dense plug 55 during manufacture of the wafer placement table 10. Here, the case in which the electrically conductive plate 30 is made from an MMC will be illustrated. First, the ceramic plate 20 incorporating the electrode 22 is prepared (FIG. 8A). For example, a molded body of ceramic powder, incorporating the electrode 22, is made, and the ceramic plate 20 is obtained by firing the molded body by hot pressing. The ceramic plate penetrating portions 50 are formed in the ceramic plate 20 (FIG. 8B). The ceramic plate penetrating portions 50 are formed so as to extend through the ceramic plate 20 in the up and down direction off the electrode 22.

Concurrently, two MMC disk members 81, 82 are prepared (FIG. 8C). Grooves and holes are formed as needed in the MMC disk members 81, 82 by machining (FIG. 8D). Specifically, recessed grooves 32a that will be finally the refrigerant flow paths 32 are formed on the lower surface of the upper-side MMC disk member 81, and recessed grooves 31 that will be finally the gas second passages 62 are formed on the upper surface of the MMC disk member 81. Through-holes 61a that will be finally parts of the gas first passages 61 are formed so as to extend from the recessed grooves 31 to the lower surface of the MMC disk member 81. In addition, through-holes 61b that will be finally parts of the gas first passages 61 are formed in the lower-side MMC disk member 82. When the ceramic plate 20 is made of alumina, the MMC disk members 81, 82 are preferably made of SiSiCTi or AlSiC. This is because the coefficient of thermal expansion of alumina and the coefficient of thermal expansion of SiSiCTi or AlSiC are almost the same.

The disk member made of SiSiCTi can be made by, for example, as follows. Initially, a powder mixture is made by mixing silicon carbide, metal Si and metal Ti. After that, a disk-shaped molded body is made by uniaxial pressing of the obtained powder mixture, and the molded body is sintered by hot pressing in an inert atmosphere, with the result that the disk member made of SiSiCTi is obtained.

Subsequently, after the ceramic plate 20, the MMC disk member 81, and the MMC disk member 82 are joined together, an overall shape is finished and the dense plug 55 is mounted to obtain the wafer placement table 10 (FIGS. 8E and 8F). Specifically, first, a first laminate is obtained by sandwiching a metal joint material 83 between an upper surface of the lower MMC disk member 82 and a lower surface of the upper MMC disk member 81. In the metal joint material 83, a through-hole to finally become part of the first gas passage 61 is formed in advance. Subsequently, for example, the two MMC disk members 81 and 82 are joined by the metal joint material 83 by TCB (Thermal Compression Bonding) to obtain the electrically conductive plate 30. TCB is a known method in which a metal joint material is sandwiched between two members to be joined, the laminate is heated to a temperature at or below the solidus temperature of the metal joint material (for example, at or below the solidus temperature and at or above a temperature lower by 20° C. than the solidus temperature), and the two members are pressure-bonded. As the metal joint material 83, an Al—Mg-based joint material or an Al—Si—Mg-based joint material can be used. For example, when TCB is performed using an Al—Si—Mg-based joint material, the laminate is pressurized while heated in a vacuum atmosphere. It is preferable to use the metal joint material 83 having a thickness of about 100 μm. Subsequently, a second laminate is obtained by sandwiching, in this order, a sheet-like resin joint material 91, a metal joint material 95, and a resin joint material 92 between the lower surface of the ceramic plate 20 and the upper surface of the electrically conductive plate 30. In the resin joint materials 91, the metal joint material 95, and the resin joint materials 92 through-holes each of which will finally become part of the joint layer penetrating portion 64 are formed in advance. After the resin joint material 91 is disposed on the upper surface of the electrically conductive plate 30, the plate spring 72 is inserted in advance into the through-hole of the resin joint material 91. Then, by heating and pressurizing the second laminate, the ceramic plate 20 and the electrically conductive plate 30 are joined by the resin joint material 91, the metal joint material 95, and the resin joint material 92. As a result, the resin joint material 91, the metal joint material 95, and the resin joint material 92 become the joint layer 40 (the first insulator layer 41, the first electrically conductive layer 45, and the second insulator layer 42).

Mounting of the dense plug 55 is carried out, for example, as follows. First, a dense plug 55 previously formed by firing is prepared, and a covering layer 71 is formed on a lower surface of the dense plug 55. Thereafter, the dense plug 55 is inserted from above into the ceramic plate penetrating portion 50 (FIG. 9A), the covering layer 71 on the lower surface of the dense plug 55 is brought into contact with the plate spring 72, and the dense plug 55 is further pressed downward (FIG. 9B). Thus, the dense plug 55 is press-fitted into the ceramic plate penetrating portion 50, and the dense plug 55 presses the plate spring 72 (the dense plug 55 presses the plate spring 72 via the covering layer 71), whereby the plate spring 72 is elastically deformed (FIG. 9B). Consequently, in the manufactured wafer placement table 10, the plate spring 72 is disposed in a state extended in the crosswise direction perpendicular to the up-down direction. That is, the plate spring 72 extends from a horizontal width W1 (FIG. 9A) which is a natural length before being pressed by the dense plug 55 to change to a width W2 larger than the width W1 (FIG. 9B). Along with this horizontal extension, an up-down height T1 (FIG. 9A) of the plate spring 72 before being pressed by the dense plug 55 changes to a height T2 smaller than the height T1 (FIG. 9B). Thus, as described above, not only a crosswise elastic force but also an up-down elastic force is generated, and the upper surface 72a of the plate spring 72 presses the dense plug 55 upward. In this way, by not only bringing the dense plug 55 into contact with the plate spring 72 via the covering layer 71 but also press-fitting the dense plug 55 into the ceramic plate penetrating portion 50 so that the dense plug 55 presses the plate spring 72 downward, the dense plug 55 can be brought into even more reliable contact with the plate spring 72 via the covering layer 71, so that the covering layer 71 and the plate spring 72 can be made even more reliably electrically conductive with each other. In addition, the plate spring 72 and the first electrically conductive layer 45 can be made even more reliably electrically conductive with each other.

In the wafer placement table 10 described in detail above, the joint layer 40 that joins the ceramic plate 20 and the electrically conductive plate 30 has the structure in which the insulator layer 40a and the electrically conductive layer 40b are laminated. Since, in general, a conductor has a lower thermal resistance than an insulator, by the joint layer 40 having the insulator layer 40a, as compared with a case in which the joint layer 40 is entirely constituted of a conductor, the thermal resistance of the joint layer 40 can be made higher more easily. Therefore, in this wafer placement table 10, heat conduction from the ceramic plate 20 to the electrically conductive plate 30 can be suppressed and cooling of the wafer W can be suppressed. Further, since the electrically conductive layer 40b (here, the first electrically conductive layer 45) is exposed in the joint layer penetrating portion 64, which is the portion of the gas introduction passage 60 that penetrates the joint layer 40, discharge can be suppressed in the vicinity of the end on the electrically conductive plate 30 side among the ends of the dense plug 55, that is, in the vicinity of the lower end of the dense plug 55. From the foregoing, in this wafer placement table 10, discharge in the vicinity of the end on the electrically conductive plate 30 side among the ends of the dense plug 55 can be suppressed while suppressing cooling of the wafer W.

Here, regarding the temperature of the wafer W during use of the wafer placement table 10, in recent years, higher temperatures have been required, and to make the wafer W at a higher temperature, it is necessary to further increase the thermal resistance of the joint layer 40. When the thermal resistance is increased by making the joint layer 40 thicker, since the up-down length of the joint layer penetrating portion 64 becomes larger, if the joint layer 40 is entirely constituted of an insulator, a potential difference is likely to occur on the inner peripheral surface of the joint layer penetrating portion 64 in the joint layer 40, and discharge tends to occur inside the joint layer penetrating portion 64. However, in the wafer placement table 10 of this embodiment, since the joint layer 40 includes the first electrically conductive layer 45 exposed in the joint layer penetrating portion 64, discharge can be suppressed by the first electrically conductive layer 45. Moreover, since the joint layer 40 includes the first insulator layer 41 and the second insulator layer 42, as compared with a case in which the entire joint layer 40 is a conductor, the thermal resistance of the joint layer 40 can be increased even at the same thickness. In this embodiment, although the first electrically conductive layer 45 and the electrically conductive plate 30 are not directly electrically connected, because a voltage causing discharge during use of the wafer placement table 10 is an alternating voltage such as a radio-frequency (RF) voltage, a potential can be supplied from the electrically conductive plate 30 to the first electrically conductive layer 45 by capacitive coupling between the electrically conductive plate 30 and the first electrically conductive layer 45. Therefore, discharge in the joint layer penetrating portion 64 can be suppressed by the first electrically conductive layer 45.

Further, by making the distance L1 between the lower surface of the ceramic plate 20 and the first electrically conductive layer 45 in the up-down direction 200 μm or less, the height of a space between the lower surface of the dense plug 55 and the upper surface of the first electrically conductive layer 45 in the gas introduction passage 60 becomes small, and therefore the effect of suppressing discharge in the vicinity of the end on the electrically conductive plate 30 side among the ends of the dense plug 55, that is, in the vicinity of the lower end of the dense plug 55, is enhanced. By making the distance L1 100 μm or less, this effect is further enhanced. Likewise, by making the distance L2 between the upper surface of the electrically conductive plate 30 and the first electrically conductive layer 45 in the up-down direction 200 μm or less, the height of the space (here, the same as the height of the through-hole 64c) between the lower surface of the first electrically conductive layer 45 and the upper surface of the electrically conductive plate 30 among the gas introduction passage 60 becomes small, and therefore the effect of suppressing discharge in this space is also enhanced. By making the distance L2 100 μm or less, this effect is further enhanced.

Furthermore, the wafer placement table 10 includes the electrically conductive gas passage member 70 that is provided in the gas introduction passage 60, contacts the lower surface of the dense plug 55, is electrically connected to the first electrically conductive layer 45, and allows gas to pass between the dense plug 55 and the gas introduction passage 60. Therefore, since the electrically conductive gas passage member 70 at the same potential as the first electrically conductive layer 45 is in contact with the dense plug 55, discharge can be suppressed in the vicinity of the end on the electrically conductive plate 30 side among the ends of the dense plug 55, that is, in the vicinity of the lower end of the dense plug 55. Note that, for example, even if an insulating porous member is present on the lower surface of the dense plug 55 instead of the electrically conductive gas passage member 70, discharge in the vicinity of the lower end of the dense plug 55 can be suppressed, but by presence of the electrically conductive gas passage member 70, a potential difference is less likely to occur in the vicinity of the end on the electrically conductive plate 30 side among the ends of the dense plug 55, and discharge can be suppressed more. In addition, the electrically conductive gas passage member 70 has the plate spring 72 that presses the dense plug 55 upward with an elastic force. This allows the dense plug 55 to be brought into even more reliable contact with the plate spring 72 via the covering layer 71, so that electrical conduction from the contact portion (here, the upper surface of the covering layer 71) with the dense plug 55 among the electrically conductive gas passage member 70 to the first electrically conductive layer 45 is likely to be maintained.

In addition, the plate spring 72 is disposed in the state extended in the crosswise direction perpendicular to the up-down direction by being pressed from above by the dense plug 55. Thus, as the plate spring 72 extends and spreads laterally, it becomes easy to reduce a region directly under the dense plug 55 where the plate spring 72 is absent. Accordingly, discharge in the vicinity of the end on the electrically conductive plate 30 side among the ends of the dense plug 55 can be further suppressed. For example, in a case where, even in the wafer placement table 10 after manufacture, the plate spring 72 is in a state not extended laterally as in FIG. 9A, there is a concern that the effect of suppressing discharge in a space on the left or right of the plate spring 72 of a space directly under the dense plug 55 becomes small. In contrast, by the plate spring 72 extending laterally as in FIG. 9B, the effect of suppressing discharge is enhanced. Further, for example, when a case arises where the plate spring 72 is desired to be replaced in the wafer placement table 10, such as when the elastic force of the plate spring 72 decreases with long-term use of the wafer placement table 10, in the above-described embodiment, by removing the dense plug 55 from the ceramic plate 20 of the wafer placement table 10, the plate spring 72 returns to the state prior to lateral extension as in FIG. 9A (the lateral width becomes W1 which is smaller than W2), so that the plate spring 72 can be easily taken out and replacement of the plate spring 72 becomes easy.

The present invention is not limited to the above-described embodiment and may be, of course, implemented in various modes within the technical scope of the present invention.

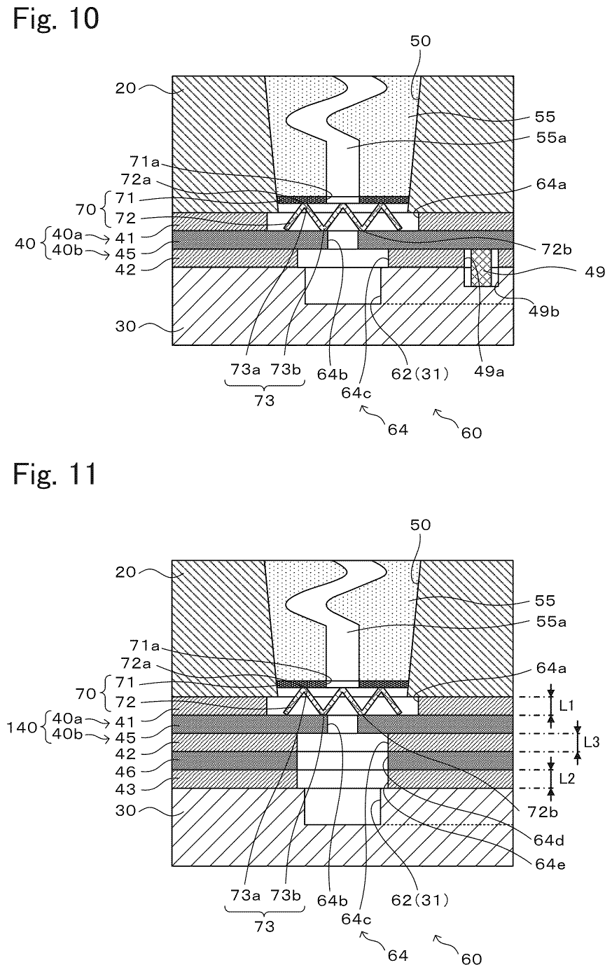

For example, in the embodiment described above, the electrically conductive plate 30 and the first electrically conductive layer 45 were not directly electrically connected, but the invention is not limited thereto. The wafer placement table 10 may further include, for example as shown in FIG. 10, a conduction member 49 that electrically connects the electrically conductive plate 30 and the first electrically conductive layer 45. In FIG. 10, the conduction member 49 is placed in a mounting hole 49b provided in the upper surface of the electrically conductive plate 30 and mounted inside the mounting hole 49b and a through-hole 49a provided in the second insulator layer 42, and contacts the first electrically conductive layer 45 and the electrically conductive plate 30 to electrically connect them. In this way, a potential can be supplied to the first electrically conductive layer 45 by electrically connecting the electrically conductive plate 30 and the electrically conductive layer 40b, so that the two can be brought to substantially the same potential. Accordingly, the effect of suppressing discharge in the vicinity of the end on the electrically conductive plate 30 side among the ends of the dense plug 55 is enhanced. In FIG. 10, since the electrically conductive gas passage member 70 (the covering layer 71 and the plate spring 72) and the first electrically conductive layer 45 are directly electrically connected, the electrically conductive gas passage member 70 and the electrically conductive plate 30 are also directly electrically connected. In FIG. 10, the conduction member 49 is disposed at a position different from the joint layer penetrating portion 64. Specifically, the conduction member 49 is disposed in the through-hole 49a and the mounting hole 49b provided at positions spaced from the joint layer penetrating portion 64. The conduction member 49 is not exposed in the joint layer penetrating portion 64. However, the invention is not limited to this, and, for example, the conduction member 49 may be disposed inside the joint layer penetrating portion 64 or disposed at a position exposed in the joint layer penetrating portion 64.

In the embodiment described above, the electrically conductive gas passage member 70 (the covering layer 71 and the plate spring 72) is directly electrically connected to the first electrically conductive layer 45, while it is not directly electrically connected to the electrically conductive plate 30; however, as described above, it suffices that the electrically conductive gas passage member 70 be electrically connected to the electrically conductive plate 30 and/or the electrically conductive layer 40b. For example, the electrically conductive gas passage member 70 may not be directly electrically connected to the first electrically conductive layer 45 and may be directly electrically connected to the electrically conductive plate 30. Specifically, the diameter of the through-hole 64b may be made larger than that in FIG. 2 and the vertical height of the plate spring 72 may be increased so that the plate spring 72 does not contact the first electrically conductive layer 45 while directly electrically connecting between the covering layer 71 and the electrically conductive plate 30.

In the embodiment described above, the insulator layer 40a has two layers, the first insulator layer 41 and the second insulator layer 42, and the electrically conductive layer 40b has one layer, the first electrically conductive layer 45; however, the invention is not limited thereto. For example, in a joint layer 140 shown in FIG. 11, the insulator layer 40a has three layers, first to third insulator layers 41 to 43, and the electrically conductive layer 40b has two layers, first and second electrically conductive layers 45 and 46. The first insulator layer 41, the first electrically conductive layer 45, the second insulator layer 42, the second electrically conductive layer 46, and the third insulator layer 43 are laminated in this order from top to bottom. A joint layer penetrating portion 64 includes, in addition to the through-holes 64a to 64c described above, a through-hole 64d provided in the second electrically conductive layer 46 and a through-hole 64e provided in the third insulator layer 43. In this case as well, since the first electrically conductive layer 45 and the second electrically conductive layer 46 are exposed in the joint layer penetrating portion 64, discharge can be suppressed by these layers. Also in FIG. 11, similarly to the embodiment described above, the distance L1 between the lower surface of the ceramic plate 20 and the insulator layer 40a (here, a distance between the lower surface of the ceramic plate 20 and the first electrically conductive layer 45 in the up-down direction) in the up-down direction is preferably 200 μm or less and more preferably 100 μm or less. The distance L2 between the upper surface of the electrically conductive plate 30 and the insulator layer 40a (here, a distance between the upper surface of the electrically conductive plate 30 and the second electrically conductive layer 46) in the up-down direction is preferably 200 μm or less and more preferably 100 μm or less. Further, a distance L3 between the plurality of electrically conductive layers (here, the distance between the first electrically conductive layer 45 and the second electrically conductive layer 46) in the up-down direction is preferably 200 μm or less and more preferably 100 μm or less.

In either of FIG. 2 and FIG. 11, uppermost and lowermost layers among the joint layers 40 and 140 are both insulator layers. It is preferable that portions of the joint layer that are in contact with the ceramic plate 20 and the electrically conductive plate 30 be insulator layers rather than electrically conductive layers.

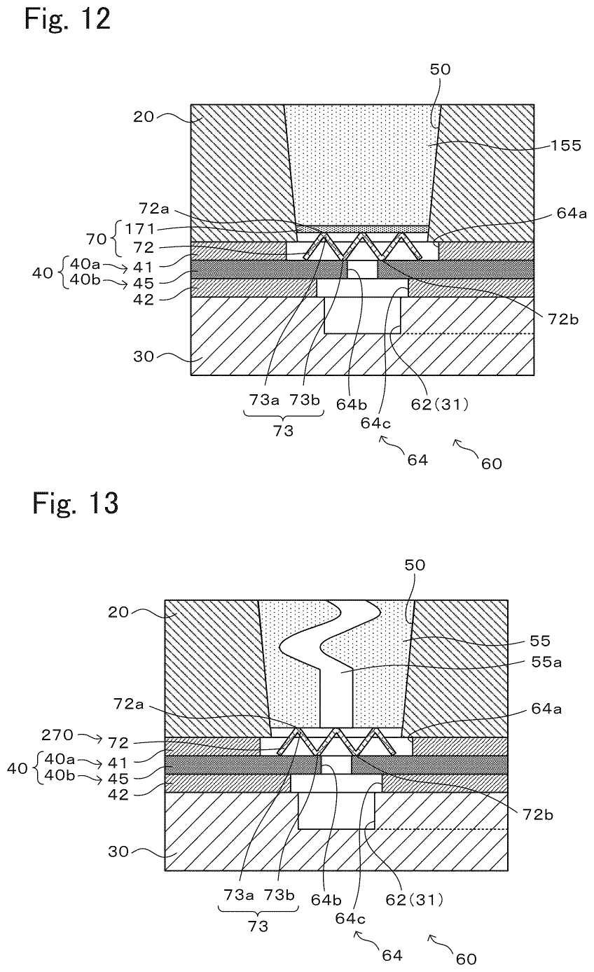

In the embodiment described above, the ceramic plate penetrating portion 50 is provided with the dense plug 55 having the gas internal passage 55a; however, the invention is not limited to the dense plug 55, and it suffices that an insulating gas passage plug allowing gas to pass through its interior be provided in the ceramic plate penetrating portion 50. For example, as the insulating gas passage plug, a porous plug may be used. Similarly for the covering layer 71, it suffices that it allows passage of gas; for example, the covering layer 71 may be a conductive porous layer without the hole 71a. For example, a porous plug 155 and a covering layer 171 shown in FIG. 12 are configured as porous bodies. The porous plug 155 can use, for example, a porous bulk body obtained by sintering using ceramic powder. As the ceramic, for example, alumina or aluminum nitride can be used. A porosity of the porous plug 155 is preferably 30% or more, and an average pore diameter is preferably 20 μm or more. The porosity of the porous plug 155 may be 70% or less. By using porous plating, the covering layer 171 as a metal porous layer can be formed on the lower surface of the porous plug 155. The dense plug 55 and the covering layer 171 may be combined, or the porous plug 155 and the covering layer 71 may be combined. Further, in the embodiment described above, the covering layer 71 allows gas to pass by having the hole 71a; however, the covering layer 71 may cover a part of the lower surface of the dense plug 55 and allow gas to pass through a portion of the lower surface that is not covered.

In the embodiment described above, the electrically conductive gas passage member 70 may not have the covering layer 71. For example, an electrically conductive gas passage member 270 shown in FIG. 13 has no covering layer 71 and has the plate spring 72. In FIG. 13, the upper surface 72a of the plate spring 72 directly contacts the dense plug 55 and presses the dense plug 55 upward with an elastic force. Even in this case, as in the embodiment described above, discharge in the vicinity of the end on the electrically conductive plate 30 side among the ends of the dense plug 55, that is, in the vicinity of the lower end of the dense plug 55, can be suppressed.

In the embodiment described above, the plate spring 72 is disposed in a state extended in a crosswise direction perpendicular to the up-down direction by being pressed from above by the dense plug 55; however, the invention is not limited thereto, and the plate spring 72 need not be extended in the crosswise direction. For example, the plate spring 72 may be arranged so that its principal expansion/contraction direction becomes the up-down direction, such as by rotating the plate spring 72 of FIG. 2 by 90° and arranging the plate spring 72 in a lengthwise. Even with this arrangement, the plate spring 72 can press the dense plug 55 upward with an elastic force.

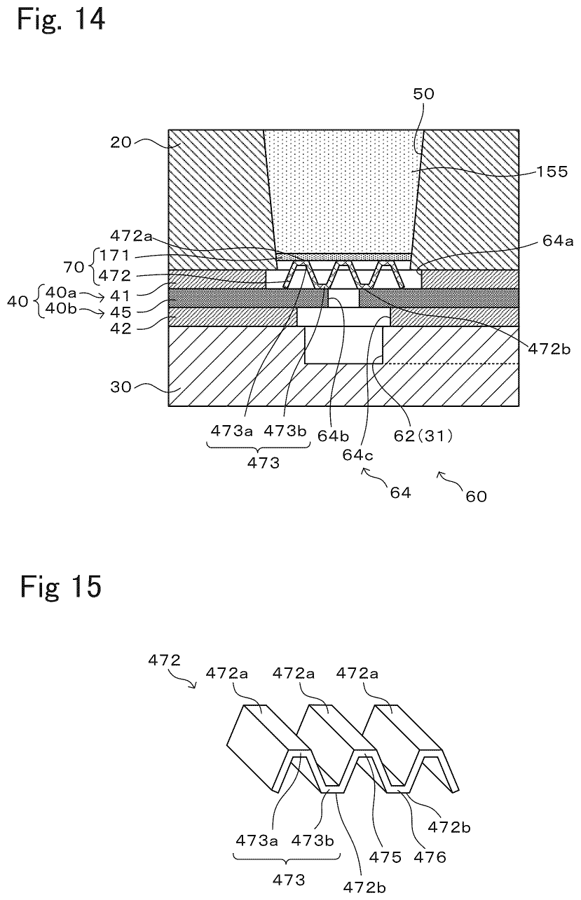

In the embodiment described above, the return portion 73 of the plate spring 72 is formed in a V-shape; however, the invention is not limited thereto. For example, the wafer placement table 10 may include, instead of the plate spring 72, a plate spring 472 shown in FIGS. 14 and 15. In FIG. 14, as in FIG. 12, a case is illustrated where the wafer placement table 10 includes the porous plug 155 and the covering layer 171 instead of the dense plug 55 and the covering layer 71. The plate spring 472 has a plurality of return portions 473 returned along the up-down direction. As the plurality of return portions 473, the plate spring 472 has one or more (a plurality, specifically three here) first return portions 473a returned from above to below and one or more (a plurality, specifically two here) second return portions 473b returned from below to above. Accordingly, the number of times of return of the plate spring 472 is five. The first return portion 473a extends along the horizontal direction and has a first plate portion 475 whose upper surface constitutes an upper surface 472a of the plate spring 472. The second return portion 473b extends along the horizontal direction and has a second plate portion 476 whose lower surface constitutes a lower surface 472b of the plate spring 472. Accordingly, each of the plurality of return portions 473 of the plate spring 472 has a shape having an upper base portion of a trapezoid and slanted sides on both sides, rather than a V-shape. The plate spring 472 shown in FIGS. 14 and 15 is, similarly to the plate spring 72, disposed in a state extended in a crosswise direction perpendicular to the up-down direction by being pressed from above by the porous plug 155. By the plate spring 472 having the first plate portion 475, for example, a horizontal width of the upper surface 472a can be made wider than the upper surface 72a of the plate spring 72 in FIG. 2. Therefore, a contact area between the upper surface 472a and a member above the plate spring 472 (here, the covering layer 171) can be increased. Similarly, by the plate spring 472 having the second plate portion 476, a horizontal width of the lower surface 472b can be made wider than the lower surface 72b of the plate spring 72 in FIG. 2. Therefore, a contact area between the lower surface 472b and a member below the plate spring 472 (here, the first electrically conductive layer 45) can be increased. By these, the plate spring 472 can be brought into more reliable contact with the members above and below it, and hence electrical conduction from the contact portion with the porous plug 155 among the electrically conductive gas passage member 70 to the electrically conductive plate 30 and/or the first electrically conductive layer 45 can be maintained more reliably. Also, since the contact area between the plate spring 472 and the members above and below it is large, a contact resistance can be reduced, and the effect of suppressing discharge in the vicinity of the lower end of the porous plug 155 is enhanced. Incidentally, the plate spring 72 of the embodiment described above may be said to be a shape obtained by omitting the first plate portion 475 and the second plate portion 476 from the plate spring 472.

In the embodiment described above, the plate spring 72 has a shape in which a metal plate is bent in a zigzag; however, the invention is not limited thereto. For example, the plate spring 72 may be a U-shaped plate spring.

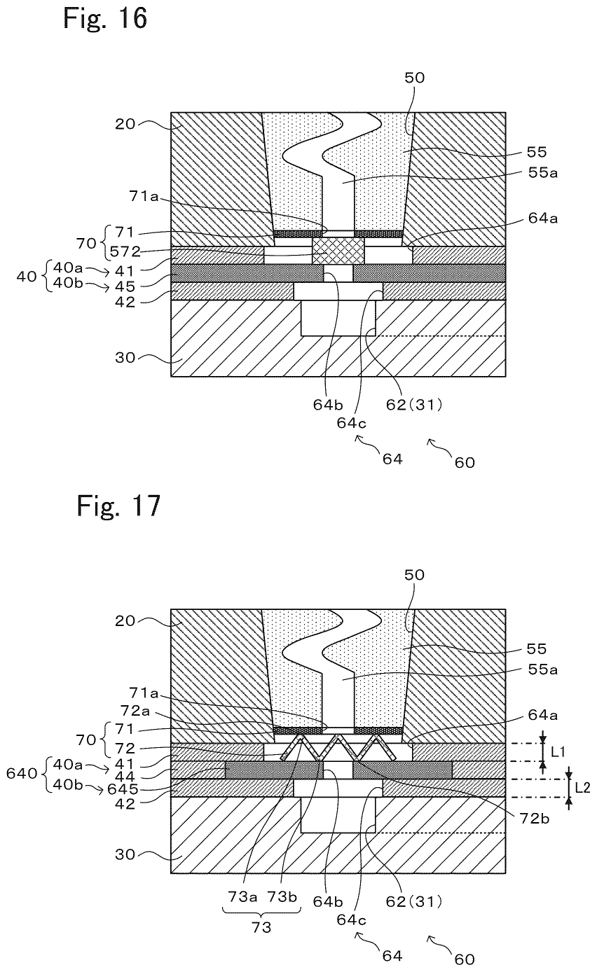

In the embodiment described above, the plate spring 72 is exemplified as an example of the electrically conductive elastic body included in the electrically conductive gas passage member 70; however, the invention is not limited thereto. For example, as shown in FIG. 16, the electrically conductive gas passage member 70 may include, instead of the plate spring 72, an electrically conductive elastic body 572. The electrically conductive elastic body 572 is, for example, a substantially columnar member that is circular in plan view and is in contact with and electrically connected to the covering layer 71 and the first electrically conductive layer 45. The electrically conductive elastic body 572, similarly to the plate spring 72, presses the dense plug 55 upward with an elastic force. The electrically conductive elastic body 572 presses the first electrically conductive layer 45 and the electrically conductive plate 30 downward with an elastic force. The electrically conductive elastic body 572 is preferably a member that allows gas to pass through its interior. Examples of the electrically conductive elastic body 572 include a conductive mesh and a mass of conductive fibers. Examples of the material of the electrically conductive elastic body 572 include a metal material, carbon and so forth. Examples of the metal material include Al, Ti, Mo or alloys thereof, steel and so forth. Examples of the mass of conductive fibers include steel wool, carbon felt and so forth. The electrically conductive elastic body 572 may be a conductive porous body. Examples of the conductive porous material include SiC, SiSiC and so forth.

In the embodiment described above, the joint layer 40 as a whole is a laminate of the insulator layer 40a and the electrically conductive layer 40b, but the invention is not limited thereto as long as the joint layer 40 has a structure in which the insulator layer 40a and the electrically conductive layer 40b are laminated. For example, in a joint layer 640 shown in FIG. 17, a first electrically conductive layer 645 included in the electrically conductive layer 40b is disposed only in the vicinity of the joint layer penetrating portion 64, and, in a region between the first insulator layer 41 and the second insulator layer 42 in which the first electrically conductive layer 645 is not present, a fourth insulator layer 44 is disposed. That is, the joint layer 640 has, in a peripheral region of the joint layer penetrating portion 64, a structure in which the insulator layer 40a and the electrically conductive layer 40b are laminated (the first insulator layer 41, the first electrically conductive layer 645, and the second insulator layer 42 are laminated), and in other regions, the first insulator layer 41, the fourth insulator layer 44, and the third insulator layer 43 are laminated and no electrically conductive layer is present. Also in this joint layer 640, since the first electrically conductive layer 645 is exposed in the joint layer penetrating portion 64, discharge in the vicinity of the end on the electrically conductive plate 30 side among the ends of the dense plug 55 can be suppressed by the first electrically conductive layer 645 similarly to the embodiment described above. In FIG. 17, since the first insulator layer 41, the fourth insulator layer 44, and the second insulator layer 42 are all insulators, they may be integrated and in a state in which their boundaries are not clear.

In the embodiment described above, the diameter of the through-hole 64b was smaller than the diameters of the through-holes 64a and 64c; however, the invention is not limited thereto. For example, the diameter of the through-hole 64b may be the same as or larger than the diameter of the through-hole 64c. The through-holes 64a to 64c may have the same diameter.

In the embodiment described above, the second gas passage 62 and the gas auxiliary passage 63 may be omitted, and a plurality of first gas passages 61 and a plurality of ceramic plate penetrating portions 50 may be made to communicate in one-to-one correspondence. In this case, a first gas passage 61 that penetrates the electrically conductive plate 30 in the up-down direction may be provided directly below the joint layer penetrating portion 64 in the enlarged sectional view of FIG. 2.

In the embodiment described above, the electrostatic electrode is incorporated in the ceramic plate 20 as the electrode 22. Instead of or in addition to this, a heater electrode (resistance heating element) may be incorporated. In this case, a heater power supply is connected to the heater electrode. The ceramic plate 20 may incorporate one layer of electrode or may incorporate two or more layers of electrode with a gap.

In the embodiment described above, the ceramic plate 20 is made by firing a molded body of ceramic powder by hot pressing. The molded body at that time may be made by laminating a plurality of tape-molded bodies, or may be made by mold casting method, or may be made by compacting ceramic powder.

In the embodiment described above, the dense plug 55 is fixed by being press-fitted into the ceramic plate penetrating portion 50; however, the invention is not limited thereto. For example, an outer peripheral surface of the dense plug 55 and an inner peripheral surface of the ceramic plate penetrating portion 50 may be bonded, or a male threaded portion provided on an outer peripheral surface of the dense plug 55 may be screwed into a female threaded portion provided on an inner peripheral surface of the ceramic plate penetrating portion 50.

What is claimed is:

1. A wafer placement table comprising:
a ceramic plate having a wafer placement surface on its upper surface and incorporating an electrode;
an electrically conductive plate disposed on a lower-surface side of the ceramic plate;
a joint layer joining the ceramic plate and the electrically conductive plate;
a ceramic plate penetrating portion extending through the ceramic plate;
an insulating gas passage plug provided in the ceramic plate penetrating portion and allowing gas to pass through its interior;
a gas introduction passage provided at least inside the joint layer and the electrically conductive plate, and communicating with the ceramic plate penetrating portion; and
wherein the joint layer has a structure in which an insulator layer and an electrically conductive layer are laminated, and
the electrically conductive layer is exposed in a joint layer penetrating portion which is a portion of the gas introduction passage that penetrates the joint layer, and
further comprising a conduction member that electrically connects the electrically conductive plate and the electrically conductive layer.

2. The wafer placement table according to claim 1,
wherein the conduction member is disposed at a position different from the joint layer penetrating portion.

3. The wafer placement table according to claim 1,
wherein a distance L1 between the lower surface of the ceramic plate and the electrically conductive layer in an up-down direction is 200 μm or less.

4. The wafer placement table according to claim 3,
wherein the distance L1 is 100 μm or less.

5. The wafer placement table according to claim 1,
further comprising an electrically conductive gas passage member that is provided in the gas introduction passage, contacts a lower surface of the insulating gas passage plug, is electrically connected to the electrically conductive plate and/or the electrically conductive layer, and allows gas to pass between the insulating gas passage plug and the gas introduction passage.

6. The wafer placement table according to claim 5,
wherein the electrically conductive gas passage member includes an electrically conductive elastic body that presses the insulating gas passage plug upward with an elastic force.

7. The wafer placement table according to claim 6,
wherein the electrically conductive elastic body is a plate spring.

8. The wafer placement table according to claim 5,
wherein the electrically conductive gas passage member includes a covering layer that covers the lower surface of the insulating gas passage plug.
